(19) United States
(12) Patent Application Publication
(10) Pub. No.: US 2026/0371951 A1
(43) Pub. Date: Nov. 19, 2026

(54) METAL DOPED CARBON NON-CONFORMAL DEPOSITION

(71) Applicant: Lam Research Corporation, Fremont, CA (US)

(72) Inventors: Sonal Bhadauriya, Beaverton, OR (US); Ragesh Puthenkovilakam, Portland, OR (US); Kapu Sirish Reddy, Portland, OR (US)

(21) Appl. No.: 19/133,505

(22) PCT Filed: Nov. 10, 2023
(86) PCT No.: PCT/US2023/079420

§ 371 Date: May 28, 2025

Related U.S. Application Data
(60) Provisional application No. 63/385,559, filed on Nov. 30, 2022.

(51) Int. Cl. H10P 14/60; C23C 16/32; C23C 16/455; H10P 14/69; H10P 50/00

(52) U.S. Cl. CPC H10P 14/6336; C23C 16/32; C23C 16/45536; H10P 14/6907; H10P 50/73

(57) ABSTRACT

Methods and apparatuses for forming non-conformal metal-doped films on patterned semiconductor substrates to facilitate deeper etching of features are provided. Selective deposition and etch back of a tungsten-doped carbide film can be tuned to configure desired shapes. Shapes with rounded profiles such as helmet-shaped films may be laid over the patterned mask layer, providing selectivity benefits.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor fabrication processes involve patterning operations, including depositing and etching of various materials on a semiconductor substrate. Substrates include features of various types, including horizontal and vertical features, negative features with sloped sidewalls, features with re-entrant features, and features made as negative features in substrates having a multi-layered stack of two or more materials.

For instance, such processes are commonly used in memory applications such as fabricating 3D NAND structures. As the semiconductor industry advances and device dimensions become smaller, such features are increasingly difficult to etch in a uniform manner, especially for high aspect ratio (HAR) structures where narrow widths and/or deep depths are desirable.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods and apparatuses for forming non-conformal metal-doped films on patterned semiconductor substrates to facilitate deeper etching of features. Metal-doped films have higher selectivity than carbon hardmasks. By utilizing process conditions for deposition and etch back of a tungsten-doped carbide film on top of partially etched features tungsten-doped carbon films can be deposited on top of etched features for a selectivity benefit. These metal doped films can be grown non-conformally on top of partial etches features in configurations forming desired shapes, such as a helmet-shaped film. The helmet-shaped film is laid over the patterned mask layer. It serves to protect the patterned mask layer from damage and provide selectivity benefit.

Accordingly, in a first aspect, the present disclosure encompasses a method of forming a non-conformal metal-doped film on a patterned semiconductor substrate. In some embodiments, the method includes providing a patterned semiconductor substrate in a process chamber, the patterned semiconductor substrate including a patterned mask layer; and exposing the patterned semiconductor substrate to one or more cycles of (i) plasma-enhanced chemical vapor deposition and (ii) etching, wherein each cycle includes exposure to a metal-containing precursor, a hydrocarbon precursor and a reducing agent for 10 to about 150 seconds, to deposit a metal-doped carbon-containing layer over the patterned mask layer; and exposure of the metal-doped carbon-containing layer over the patterned mask layer to an etchant for one to about 60 seconds, to form a non-conformal metal-doped film over the patterned mask layer.

In some embodiments, the non-conformal metal-doped film is tungsten-doped carbide, tungsten-doped carbonitride, ruthenium-doped carbonitride, ruthenium-doped carbide, molybdenum-doped carbide or a combination thereof.

In some embodiments, the hydrocarbon precursor is methane, ethane, ethylene, propylene, propyne, propane, butane, butylene, butadiene, acetylene or a combination thereof.

In some embodiments, the reducing agent is hydrogen, ammonia, hydrazine, silane, disilane, trisilane, germane, digermane, diborane or a combination thereof.

In some embodiments, the etchant is hydrogen, ammonia, boron trifluoride, nitrogen trifluoride, sulfur hexafluoride, phosphorus pentafluoride, tungsten hexafluoride or a combination thereof.

In some embodiments, exposing includes one to twenty cycles of plasma-enhanced chemical vapor deposition and etching.

In some embodiments, exposing includes one cycle of plasma-enhanced chemical vapor deposition and etching.

In some embodiments, one cycle of plasma-enhanced chemical vapor deposition and etching includes exposure to a metal-containing precursor, a hydrocarbon precursor and a reducing agent for 30 seconds to about 95 seconds, and exposure to an etchant for 10 seconds to about 50 seconds.

In some embodiments, the process chamber is maintained at a temperature between about 200 °C to 650 °C.

In some embodiments, the patterned semiconductor substrate includes features in the patterned mask layer and dielectric material under the patterned mask layer.

In some embodiments, the method also includes etching the dielectric material to form trenches in the dielectric material.

In some embodiments, the features in the patterned mask layer include pillars of the patterned mask layer.

In some embodiments, the non-conformal metal-doped film forms an overlayer on top of the pillars.

In some embodiments, the dielectric material includes layers of silicon oxide and polysilicon or layers of silicon oxide and silicon nitride.

In some embodiments, the one or more cycles are performed in one process chamber.

In some embodiments, the non-conformal metal-doped film over the patterned mask layer has a rounded profile.

In some embodiments, the non-conformal metal-doped film includes helmet-shaped deposits over the patterned mask layer.

In some embodiments, the non-conformal metal-doped film is tungsten-doped carbide and the metal-containing precursor is a tungsten-containing precursor.

In some embodiments, the tungsten-containing precursor is tungsten hexacarbonyl, tungsten pentachloride, tungsten hexachloride or tungsten hexafluoride.

In some embodiments, the tungsten-doped carbide includes from about 10 to about 75 percent tungsten by weight.

In a second aspect, the present disclosure encompasses an apparatus for processing patterned semiconductor substrates. In some embodiments, the apparatus includes a process chamber; a substrate support for a patterned semiconductor substrate positioned within the process chamber, the patterned semiconductor substrate having a patterned mask layer; a plasma generator configured to generate a plasma within the process chamber; one or more gas inlets into the process chambers and associated flow-control hardware; and a controller having at least one processor and a memory, wherein the at least one processor and the memory are communicatively connected with one another, the at least one processor is at least operatively connected with the associated flow-control hardware, and the memory stores computer-executable instructions for controlling the at least one processor to cause: positioning the patterned semiconductor substrate in the process chamber; and exposing the patterned semiconductor substrate to one or more cycles of plasma-enhanced chemical vapor deposition and etching, wherein each cycle includes exposure to a metal-containing precursor, a hydrocarbon precursor and a reducing agent for 10 to about 150 seconds, to deposit a metal-doped carbon-containing layer over the patterned mask layer; and exposure of the metal-doped carbon-containing layer over the patterned mask layer to an etchant for one to about 60 seconds, to form a non-conformal metal-doped film over the patterned mask layer.

These and other aspects are described further below with reference to the drawings.

### BRIEF DESCRIPTION OF THE DRAWINGS

FIG. 1 depicts a film stack on a substrate.

FIGS. 2A and 2B depict a partially fabricated structure before and after an etch, demonstrating erosion of hardmask.

FIG. 3 is a flowchart describing a method for etching a feature for a structure in accordance with certain disclosed embodiments.

FIGS. 4A and 4B depict structures having a non-conformal metal-doped film in accordance with certain disclosed embodiments.

FIG. 5 is a graph illustrating the higher etch resistance of tungsten-doped carbide (WDC) as compared to pure carbon ashable hardmask (AHM) in accordance with certain disclosed embodiments.

FIG. 6 is a graph illustrating how the shape of the non-conformal metal-doped film is affected by the duration of etching in accordance with certain disclosed embodiments.

FIGS. 7-9 are schematic illustrations of example process chambers and tools for performing certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments. The figures are not drawn to scale.

### Definitions

As used herein, the term “about” is understood to account for minor increases and/or decreases beyond a recited value, which changes do not significantly impact the desired function of the parameter beyond the recited value(s). In some cases, “about” encompasses +/−10% of any recited value. As used herein, this term modifies any recited value, range of values, or endpoints of one or more ranges.

As used herein, the terms “top”, “bottom”, “upper”, “lower”, “above”, and “below” are used to provide a relative relationship between structures. The use of these terms does not indicate or require that a particular structure must be located at a particular location in the apparatus.

As used herein, the phrase “at least one of A, B, and C” should be construed to mean a logical (A or B or C), using a non-exclusive logical “or”, and should not be construed to mean “at least one of A, at least one of B and at least one of C”.

For the purposes of this disclosure, “metal” used in this context should be understood to mean conductor with a maximum resistivity of 500 micro Ohm cm, including metals and conductive metal salts, in particular conductive metal nitrides, e.g., TiN.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like. The term “semiconductor substrate” or “substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

“Silicon oxide” is referred to herein as including any and all stoichiometric possibilities for SiₓO_{y}, including integer values of x and y and non-integer values of x and y. For example, “silicon oxide” includes compounds having the formula SiOₙ, where 1≤n≤2, where n can be an integer or non-integer values. “Silicon oxide” can include sub-stoichiometric compounds such as SiO_{1.8}. “Silicon oxide” also includes silicon dioxide (SiO₂) and silicon monoxide (SiO). “Silicon oxide” also includes both natural and synthetic variations and also includes any and all crystalline and molecular structures, including tetrahedral coordination of oxygen atoms surrounding a central silicon atom. “Silicon oxide” also includes amorphous silicon oxide and silicates.

“Silicon nitride” is referred to herein as including any and all stoichiometric possibilities for SiₓN_{y}, including integer values of x and y and non-integer values of x and y, such as x=3 and y−4. For example, “silicon nitride” includes compounds having the formula SiNₙ, where 1≤n≤2, where n can be an integer or non-integer values. “Silicon nitride” can include sub-stoichiometric compounds such as SiN_{1.8}. “Silicon nitride” also includes Si₃N₄ and silicon nitride with trace and/or interstitial hydrogen (SiNH) and silicon nitride with trace amounts of and/or interstitial oxygen (SiON). “Silicon nitride” also includes both natural and synthetic variations and also includes any and all lattice, crystalline, and molecular structures, including trigonal alpha-silicon nitride, hexagonal beta-silicon nitride, and cubic gamma-silicon nitride. “Silicon nitride” also includes amorphous silicon nitride and can include silicon nitride having trace amounts of impurities.

By “etchant” is meant any compound used to remove a material such as a layer, byproduct or contaminant from a surface.

By “shaped” is meant having a particular form or contour which is other than a planar or conformal.

By “rounded profile” is meant a shape of a structure including, but not limited, to one with rounded upper edges such as one which has a bread loaf or helmet shape in a cross-sectional view.

### Introduction & Context

Recent advances in semiconductor fabrication technology have allowed for increasing the density of elements, such as memory cells in a memory device, on a substrate. For example, in 3D NAND technology tall structures are designed in order to improve device density scaling. New challenges arise from the increased size of these structures. As described herein, novel materials and processing techniques have been developed to address these challenges, including large area gap fill.

In typical current 3D NAND manufacturing, the “mold stack” comprising a stack of 24 to 64 pairs of oxide and nitride layers (such as, silicon oxide (SiO₂)/silicon nitride (Si₃N₄) layers) is typically deposited in a plasma-enhanced chemical vapor deposition (PECVD) dielectric deposition tool. The film stack including alternating oxide and nitride layers may be referred to as an ONON stack.

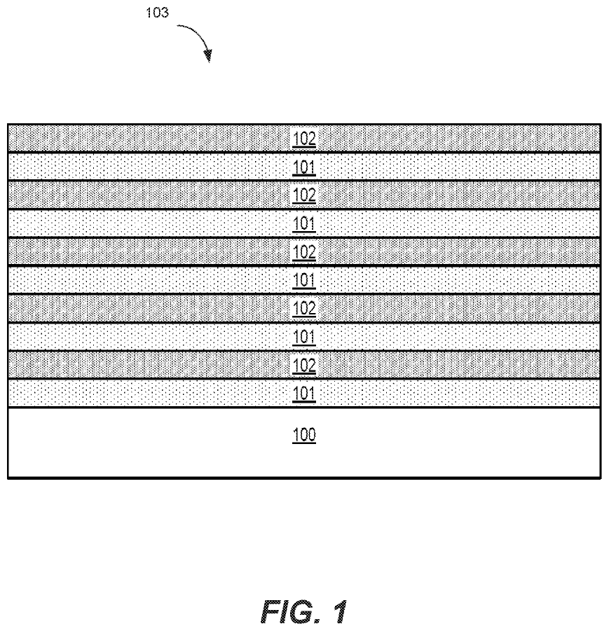

FIG. 1 illustrates an ONON stack for 3D NAND structure 103, depicting alternating oxide (101) and nitride (102) films deposited on substrate 100. The structure 103 depicts an oxide first, followed by nitride, oxide, nitride, etc.; however, in some embodiments, nitride may be deposited first, followed by oxide, nitride, oxide, etc. A stack of alternating layers of other materials may be employed. For example, an OPOP stack (alternating layers of silicon oxide and polysilicon) may also be represented by structure 103, where the alternating films are oxide (101) and polysilicon (102).

The SiO₂ layer and Si₃N₄ layer are deposited sequentially on each station (also referred to as a pedestal) without moving the wafer until the entire stack, or a substantial fraction of the stack, is deposited. Vertical channels are then etched down through the oxide and nitride layers in the mold stack by high aspect ratio etching and filled with metal to form contacts. Then, a thick photoresist layer is applied and patterned, one set of oxide/nitride pairs is etched and then the photoresist pattern is shrunken and the next pair of oxide/nitride layers is etched. This sequence is repeated to create a stair step structure at the edge of the array. After a thick oxide layer is deposited and planarized, a word line slot mask is applied and a slot is etched down through all of the oxide/nitride layer pairs. The nitride layers are then etched out through the word line slot. A gate stack of silicon dioxide, silicon nitride, aluminum oxide, tungsten and tantalum nitride is then deposited and etched back and finally the slot is filled with oxide and tungsten.

Hardmask selectivity is one of the biggest challenges in OPOP (stacked silicon oxide and polysilicon) and ONON (stacked silicon oxide and silicon nitride) memory HAR etches for 3D NAND applications. One technique for etching deeper holes without increasing the mask thickness is to increase the selectivity of the etch process. The selectivity is calculated as a ratio between the etch rate of the dielectric material and the etch rate of the mask material. For instance, if the dielectric material etches three times faster than the mask material, the etch process has a selectivity of 3:1. The selectivity of the etch process can be increased by increasing the etch rate of the dielectric material relative to the etch rate of the mask layer. Similarly, the selectivity can be increased by decreasing the etch rate of the mask layer relative to the etch rate of the dielectric material. Growing highly selective metal doped carbon films directly on top of partially etched features helps to increase the selectivity of the process.

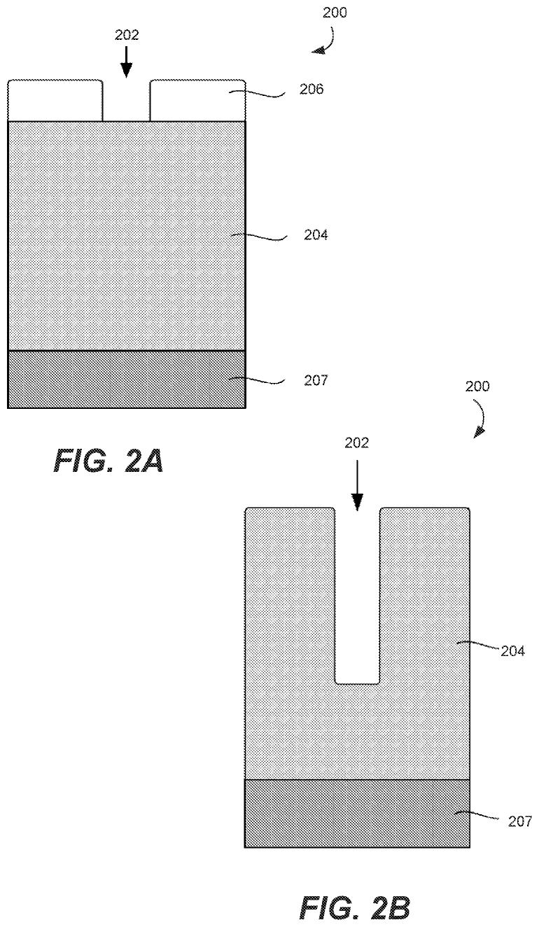

An issue which may be encountered when fabricating a 3D NAND structure with deep features is illustrated by FIGS. 2A and 2B. FIGS. 2A and 2B illustrate a partially fabricated structure as a high aspect ratio feature 202 is etched into a dielectric material layer 204 on a substrate 200. FIG. 2A shows the substrate 200 before etching begins, and FIG. 2B shows the substrate 200 after the etching is complete.

The substrate 200 includes a patterned mask layer 206 overlying the dielectric material layer 204. An underlying layer 207 is provided under the dielectric material layer 204. In various examples, the patterned mask layer 206 may have a thickness between about 300-800 nm, or between about 400-600 nm, and the dielectric material layer 204 may have a thickness between about 0.6-1.1 μm. The mask material may be polysilicon, amorphous carbon, or another common mask material known in the art. The dielectric material layer 204 typically includes silicon oxide. The underlying layer 207 may be a layer of silicon nitride, for example. In some cases, the dielectric material layer 204 may be a stack of materials including one or more layers of silicon oxide and one or more layers of silicon nitride, as illustrated in FIG. 1. The silicon nitride layers may be relatively thin compared to the silicon oxide layers.

In a particular example, the dielectric material layer 204 includes an upper layer of silicon nitride and a lower layer of silicon oxide (with the oxide being thicker than the nitride). In a similar example, the dielectric material layer 204 further includes a lower layer of silicon nitride, with the silicon oxide layer being sandwiched between the upper and lower layers of silicon nitride. The pitch between adjacent features 202 may be about 50 nm or less. The critical diameter (e.g., diameter) of the features 202 may be between about 10-30 nm, in some cases between about 15-30 nm.

The substrate 200 is shown in FIG. 2A is provided to a semiconductor processing apparatus for etching. An appropriate apparatus is described further below. After the substrate is introduced to the processing apparatus, a plasma is generated in the processing apparatus. The plasma may interact directly with the substrate to cause etching on the substrate. An underlying layer 207 is provided under the dielectric material layer 204. After a period of time, a feature 202 begins to form in the dielectric material layer 204. While the patterned mask layer 206 is initially somewhat resistant to the etching conditions, over time it experiences some etching/erosion during this process.

Eventually as shown in FIG. 2B, the patterned mask layer 206 will be substantially fully removed as a result of prolonged exposure to the etching conditions. At this point the feature 202 does not extend all the way through the dielectric material layer 204. The feature 202 cannot be etched any deeper because the patterned mask layer 206 has been substantially fully removed. Any further etching would substantially erode the dielectric material layer 204 in an undesirable manner. FIGS. 2A and 2B thus illustrate a problem frequently encountered when etching high aspect ratio features. Often, various processing considerations limit the thickness of the mask layer that can be used for a particular application which in turn limits the depth of the features that can be formed using the patterned mask layer.

The method of forming a non-conformal metal doped film can be advantageously utilized to improve selectivity for etching. By growing a vertical highly selective material such as WDC on top of partially etched features selectivity can be regained. This vertically-grown layer is a HM with a lower etch rate and gives the boost in selectivity. Such methods enable formation of deeper features without having to increase the thickness of the mask layer by formation of substantially vertical protective layer. Similarly, such methods enable formation of features at a particular etch depth with a relatively thinner mask than was previously required. As such, the techniques described herein are advantageous for both etching deeper features and for minimizing the amount of mask material required.

### Methods for Making a Non-Conformal Metal-Doped Film

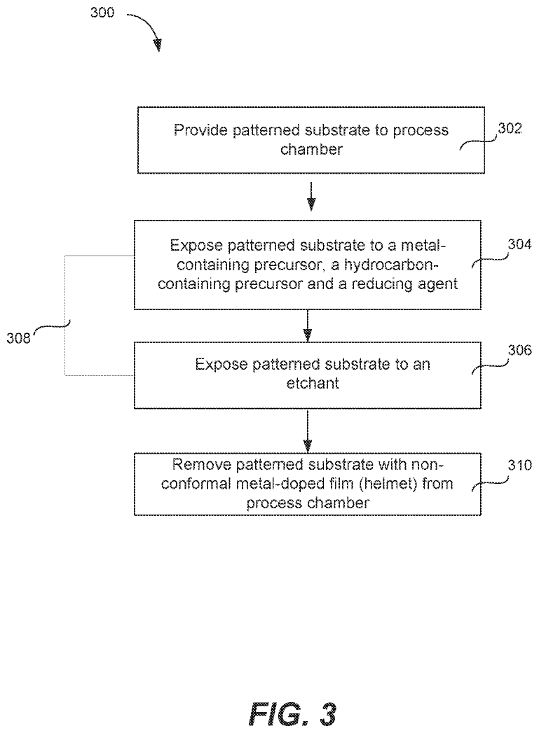

FIG. 3 is a flowchart describing a method 300 for etching a feature for a structure in accordance with certain disclosed embodiments. The method begins with operation 302, where a patterned substrate is provided to a process chamber of a semiconductor processing apparatus. An appropriate apparatus for the process is described further below. The substrate includes a patterned mask layer as described above. The substrate includes features in the patterned mask layer, and dielectric material under the patterned mask layer.

Operation 304 is a PECVD deposition step which includes exposing the patterned substrate to a metal-containing precursor, a hydrocarbon-containing precursor and a reducing agent. The hydrocarbon-containing precursor may be delivered in an inert carrier gas such as argon. A metal-doped carbon-containing layer may be deposited over the hardmask. In certain embodiments, some deposition may also occur on the sidewalls, but no deposition occurs at the bottom of the feature.

In various embodiments, the hydrocarbon precursor may be defined by the formula CₓH_{y}, where x is an integer between 2 and 10, and y is an integer between 2 and 24. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈). In some embodiments, the hydrocarbon precursor is methane, ethane, ethylene, propylene, propyne, propane, butane, butylene, butadiene, acetylene or a combination thereof.

The reducing agent is typically a reducing gas and maybe photoactive either alone or in combination with other chemical species present in the processing chamber. Suitable examples of reducing agents include H₂, SiH₄, NH₃, or NH₃-like compounds where the H is replaced by deuterium (e.g. NH₂D, NHD₂ or ND₃); hydrazine (N₂H₄) or other photoreactive gases that can produce an H radical such as tetramethylsilane, trimethylsilane, amines (methyl-, dimethyl- or trimethylamine or ethylamine); alkenes such as ethylene or propylene, or alkynes such as acetylene or combinations which may additionally include an inert gas or inert gas combinations. The inert gas may be He, N₂ or Ar.

In some embodiments, the reducing agent is hydrogen, ammonia, hydrazine, silane, disilane, trisilane, germane, digermane, diborane or a combination thereof.

Tungsten doping may be achieved with a variety of volatile precursors. In some embodiments halogen-containing tungsten precursors, such as WHalₓ, where Hal is a halogen (e.g., F, Cl, Br, and/or I) and x is from 2 to 6, are used. In some embodiments, a tungsten chloride is used. Tungsten chlorides include tungsten pentachloride (WCl₅), tungsten hexachloride (WCl₆), tungsten tetrachloride (WCl₄), tungsten dichloride (WCl₂), and mixtures thereof. In other examples tungsten fluoride, such as tungsten hexafluoride (WF₆) may be used. In some embodiments, the tungsten-containing precursor is tungsten hexacarbonyl (W(CO)₆), WCl₅, WCl₆ or WF₆.

In some embodiments, the amount of metal in the non-conformal metal-doped film is from about 10 to 75% or from about 4 to 60% of the film.

Ruthenium doping may be achieved, for example, using vaporizable ruthenium precursors, such as bis(ethylcyclopentadienyl)ruthenium(II), bis(pentamethylcyclopentadienyl)ruthenium, ruthenocene, and cyclopentadienylpropylcyclopentadienylruthenium(II).

Molybdenum doping may be achieved, for example, using molybdenum precursors having from two (MoL₂) to six (MoL₆) ligands where the molybdenum may be in a wide range of oxidation states ranging from 0 to +6. Suitable molybdenum precursors may also be dimolybdenum compounds having 1) two molybdenum atoms singly or multiply bonded to one another; or 2) two molybdenum atoms connected by a linking group such as a bidentate ligand. In some embodiments, the molybdenum precursors include molybdenum hexacarbonyl (Mo(CO)₆), molybdenum oxyhalide precursors such as molybdenum oxytetrachloride (MoOCl₄) or molybdenum dichloride dioxide (MoO₂Cl₂) and molybdenum haldide precursors such as molybdenum chloride ([MoCl₅]₂.

After the substrate is introduced to the process chamber 302, a plasma generating gas is provided to a process chamber in some embodiments for deposition 304. The plasma may be generated in situ (within the deposition chamber; also referred to as a direct plasma) or remotely (in a separate apparatus, external to the deposition chamber). In some embodiments, a plasma of reactive species is formed. The plasma species could include electrons, positive ions, neutral species, radicals and other plasma species. In some embodiments, a plasma is formed from at least one process gas comprising at least one reactant. In addition to the reactant, the process gas may also include a carrier gas. In some embodiments, the carrier gas is a noble gas such as argon, neon, krypton, xenon or helium. In some instances, the plasma may comprise other species, for example, nitrogen atoms, nitrogen radicals, nitrogen plasma or combinations thereof.

The composition of the plasma generating gas may be controlled to achieve a high degree of selectivity during the deposition. The flow rate of metal-containing precursor such as WF₆ may be at least about 1 sccm. In these or other cases, the flow rate of WF₆ may be about 20 sccm to about 500 sccm about 50 to about 375 sccm or about 100 to about 250 sccm. The plasma generating gas may also include one or more inert species.

In various cases, the WF₆ may represent at least about 0.02%, or at least about 0.05%, or at least about 0.1%, or at least about 0.5%, or at least about 1% of the volumetric flow rate of the plasma generating gas. In these or other cases, the WF₆ may represent about 10% or less, or about 5% or less, or about 1% or less, or about 0.05% or less, of the volumetric flow rate of the plasma generating gas.

In various cases, the following conditions may be used to generate the plasma. The plasma may be a capacitively coupled plasma. The plasma may be generated at an excitation frequency between about 13-169 MHz, for example between about 40-100 MHz (e.g., 60 MHz in a particular case), at a power level between about 200 to 20,000 Watts per 300 mm substrate. In various cases, the power level used to generate the plasma may be particularly high, for example about 4 kW or greater per 300 mm substrate, or about 5 kW or greater per 300 mm substrate. A relatively high bias may be applied to the substrate, for example to promote a high vertical etch rate. The bias may be applied to the substrate at a frequency between about 50 kHz and 10 MHz, or between about 200 kHz and 4 MHz (e.g., about 400 kHz in a particular case), at a power level between about 500 W and 60 kW per 300 mm substrate, or between about 2-60 kW per 300 mm substrate. In some cases, the power level used to bias the substrate is at least about 13 kW, or at least about 15 kW. In these or other cases, the power level used to bias the substrate may be about 60 kW or less, or about 30 kW or less, or about 20 kW or less, or about 17 kW or less. In a particular embodiment, the substrate is biased at 400 kHz, at a power level between about 13-17 kW.

The pressure within the reaction chamber may be at least about 1 Torr. In these or other cases, the pressure within the reaction chamber may be about 1 Torr to about 10 Torr, or about 2 to 8 Torr or about 3 to 6 Torr.

The substrate support on which the substrate is provided may be maintained at a temperature (e.g., through heating and/or cooling) between about 200 °C and 650 °C; or at a temperature between about 300 °C and 500 °C. In some cases, the substrate support is maintained at a temperature of at least about 500 °C, or at least about 450 °C, or at least about 400 °C, or at least about 350 °C, or at least about 300 °C. These temperatures may relate to the controlled temperature of the substrate support while the substrate is exposed to plasma.

Deposition 304 may take place in from about a 10 second duration to a 150 second duration in certain embodiments, or a 20 second to a 100 second duration, or a 30 to a 95 second duration in some embodiments. In some embodiments, the deposition may have a 90 second duration.

Returning to FIG. 3, operation 306 is an etching step. The plasma generating gas also includes one or more materials conventionally used for etching dielectric material. Such materials commonly include fluorocarbons and hydrofluorocarbons such as CF₄, C₃F₈, C₄F₈, C₄F₆, CH₂F₂, CH₃F, CHF₃, C₅F₈, C₆F₆, etc. Such materials can also include oxidants such as O₂, O₃, CO, CO₂, COS, etc. An overall flow rate of the plasma generating gas may be between about 50-500 sccm in various cases. In some cases, one or more fluorocarbon sources may be mixed (prior to or after delivery to the reaction chamber), for example to provide a desired ratio of carbon and fluorine. The metal-doped carbon-containing layer as deposited in operation 304 may be etched to shape it into a desired non-conformal shaped film. The shape may have a rounded profile and may resemble a helmet in certain embodiments. Selection of appropriate precursors and process conditions allows etching of the helmet while in some embodiments minimizing or avoiding any etching of the sidewalls or bottom of a trench.

In some embodiments, the etchants include tungsten halides such as tungsten fluoride (WF₅) or tungsten hexafluoride (WF₆) or molybdenum halides such as molybdenum chloride ([MoCl₅]₂), molybdenum tetrafluoride (MoF₄), molybdenum pentafluoride (MoF₅), molybdenum hexafluoride (MoF₆), molybdenum bromide (MoBr₂), molybdenum dichloride (MoCl₂), molybdenum tribromide (MoBr₃), molybdenum trichloride (MoCl₃), molybdenum triiodide (Mol₃), molybdenum tetrabromide (MoBr₄) or molybdenum hexachloride (MoCl₆).

In some embodiments, the etchant is chlorine (Cl₂), oxygen (O₂), fluorine (F₂), hydrogen chloride (HCl), hydrogen fluoride (HF), chlorine trifluoride (ClF₃), nitrogen trifluoride (NF₃), or a combination thereof. Examples of combinations include chlorine and oxygen; and fluorine and oxygen. In some embodiments, a single etchant may be sufficiently effective. In some embodiments a combination including more than one etchant may be utilized. If a combination of etchants is utilized, they may be flowed through delivery lines together (concomitantly), or sequentially (one following the other). In some embodiments, the etchant is hydrogen (H₂), ammonia (NH₃), boron trifluoride (BF₃), sulfur hexafluoride (SF₆), phosphorus pentafluoride (PF₅), tungsten hexafluoride (WF₆), nitrogen trifluoride (NF₃) or a combination thereof.

Etch 306 may take place in from about a 1 second duration to a 60 second duration in certain embodiments, or a 10 second to a 55 second duration, or a 20 to a 45 second duration in some embodiments. In some embodiments, the etch duration may be 15, 30 or 45 seconds long.

Operation 304 and 306 together constitute one cycle. The non-conformal metal-doped film may be prepared by completion of one or more cycles. As illustrated by flow path 308, operation 306 may be followed by a repetition of operation 304, followed by another etch 306. In some embodiments, one to twenty cycles may be utilized. In some embodiments, one to fifteen cycles or one to ten cycles may be utilized. In other embodiments, one to three cycles may be sufficient. The number of cycles will depend upon the materials and on the desired shape to be formed. The optimization of a deposition/etch cycle yields growth of a non-conformal tungsten-doped carbon containing film. The use of cycles can break the tradeoff between changes in the neck CD (critical diameter at the top of the feature) and the thickness of the non-conformal film, allowing growth of hardmask post HAR-etch and regain selectivity.

One or more cycles of deposition and etching can be executed in a single process chamber, as an in situ process in certain embodiments. Employment of an in situ process may contribute to a lower cost and/or increased throughput for semiconductor fabrication.

In some embodiments, deposition 304 has a duration of about 1 to 200 seconds and etch 406 has a duration of about 5 to 55 seconds in one cycle. In some embodiments, deposition 304 is from 10 to 150 seconds and etch 306 is from 10 to 50 seconds. When multiple cycles are utilized, each cycle may be of the same duration, or duration time for each of deposition 304 and etch 306 may be varied from cycle to cycle.

In some embodiments, tungsten-doped carbide is deposited by exposure with WF₆, H₂ and CH₄/C₃H₆ and argon gas for 10 to 150 seconds; and subsequently etched with NF₃ and a mixture of helium and argon gas for 10 to 50 seconds in 1 to 15 cycles.

When the desired shape and or particular height and width has been attained through selection of the appropriate number of cycles, precursors, and duration of the etch and deposition steps, the patterned substrate with non-conformal metal-doped film is removed from the process chamber in operation 310. Subsequently, further etching of the resultant patterned substrate with non-conformal metal-doped film may be performed. This subsequent etching creates trenches in the dielectric material; and in some embodiments, the further etching after the deposition of the non-conformal metal-doped film will result in a deeper trench feature than could otherwise be attained in the absence of protection.

The method described in FIG. 3 provides capability to grow a vertical highly selective material such as tungsten-doped carbide on top of partially etched features to gain back selectivity. The vertically-grown layer is a hardmask with a lower etch rate that boosts selectivity. The deposition and etch back process of FIG. 3 to form a hardmask layer in a selective manner therefore may advantageously increase the efficiency of the 3D NAND semiconductor fabrication process.

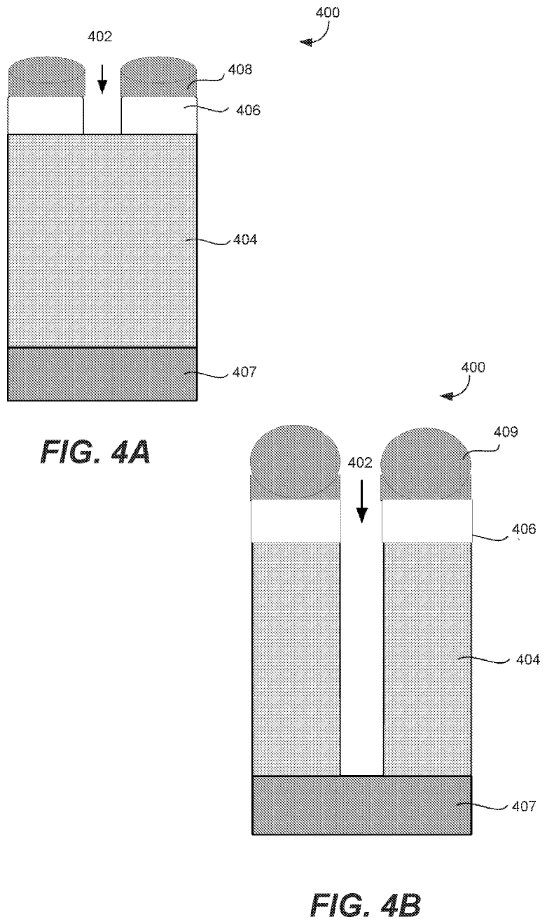

FIG. 4A depicts a non-conformal metal-doped film after a single deposit/etch cycle as described with reference to FIG. 3 above in accordance with certain disclosed embodiments.

The substrate 400 may be a silicon wafer, e.g., a 200-mm wafer, a 300-mm wafer, or a 450-mm wafer, including wafers having one or more layers of material, such as dielectric, conducting, or semi-conducting material deposited thereon. In various embodiments, the substrate is a dielectric material which is patterned. The dielectric material may be composed of layers of OPOP (stacked silicon oxide and polysilicon) or ONON (stacked silicon oxide and silicon nitride).

A patterned substrate may have “features” such as pillars, poles, trenches, via or contact holes, which may be characterized by one or more of narrow and/or re-entrant openings, constrictions within the feature, and high aspect ratios. The feature(s) may be formed in one or more of the above-described layers. One example of a feature is a pillar or pole in a semiconductor substrate or a layer on the substrate. Another example is a trench in a substrate or layer. Trenches may include a trench bottom and trench sidewalls.

In some embodiments, pillars are formed by the patterned hardmask. In some embodiments, the feature(s) such as a pillar may have an aspect ratio of at least about 1:1, at least about 2:1, at least about 4:1, at least about 6:1, at least about 10:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm. A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier. In various examples, the feature may have a width smaller in the opening at the top of the feature than the width of the bottom of the feature.

In FIG. 4A, substrate 400 includes a patterned mask layer 406 overlying the dielectric material layer 404 and a trench feature 402. An underlying layer 407 is provided under the dielectric material layer 404. The patterned mask layer 406 is a conformal layer deposited on top of dielectric material layer 404; and the conformal layer 406 is in the form of a pillar.

After one deposition/etch cycle as described above, the non-conformal metal-doped film 408 is selectively deposited over the pillars of the patterned mask layer, without being deposited on the sidewalls or bottom of trench feature 402. In some embodiments, the film is taller than it is wide. In some embodiments, the film 408 will have a substantially rounded profile. Due to the shape or appearance, the non-conformal metal-doped film is referred to as a helmet in some embodiments.

FIG. 4B illustrates how the helmet grows as further deposit/etch cycles are performed. Similar to FIG. 4A, substrate 400 includes a patterned mask layer 406 overlying the dielectric material layer 404 and feature 402. An underlying layer 407 is provided under the dielectric material layer 404. The patterned mask layer 406 is a conformal layer selectively deposited over the top of the pillars of dielectric material layer 404. As the number of deposit/etch cycles increases, the shape of the non-conformal metal-doped film changes. As shown by 409, the film's helmet-like shape may become more pronounced (i.e. taller than it is wide) in some embodiments, as the film grows vertically and the edges become rounder due to further etching in accordance with the method described with reference to FIG. 3 above.

Notably, FIG. 4B illustrates that with the non-conformal metal-doped film deposited, the hardmask beneath it is not damaged or corroded by further etching which is necessary in order to create a deeper feature. The non-conformal metal-doped film enables further deeper etching. In some embodiments, further etching can result in a feature from about 0.5 to 7 um deep or from about 1 to 5 um deep.

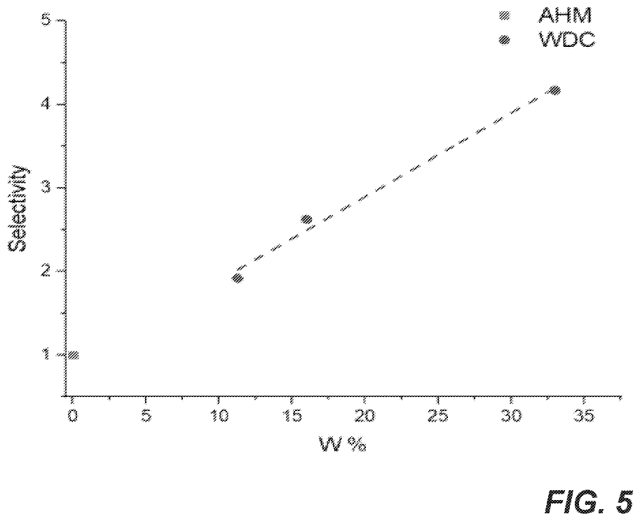

FIG. 5 is a graph illustrating the higher etch resistance of tungsten-doped carbide (WDC, represented by a round symbol) as compared to pure carbon (AHM, represented by a square symbol) with approximately 15 to 50% tungsten doping in accordance with certain disclosed embodiments. The x axis is percent of tungsten doping in a carbide film by weight and the y axis is selectivity. Thus, when tungsten-doped carbide is deposited vertically on top of partially etched features, it provides a selectivity benefit of from about 2 to 4 times that of pure carbon.

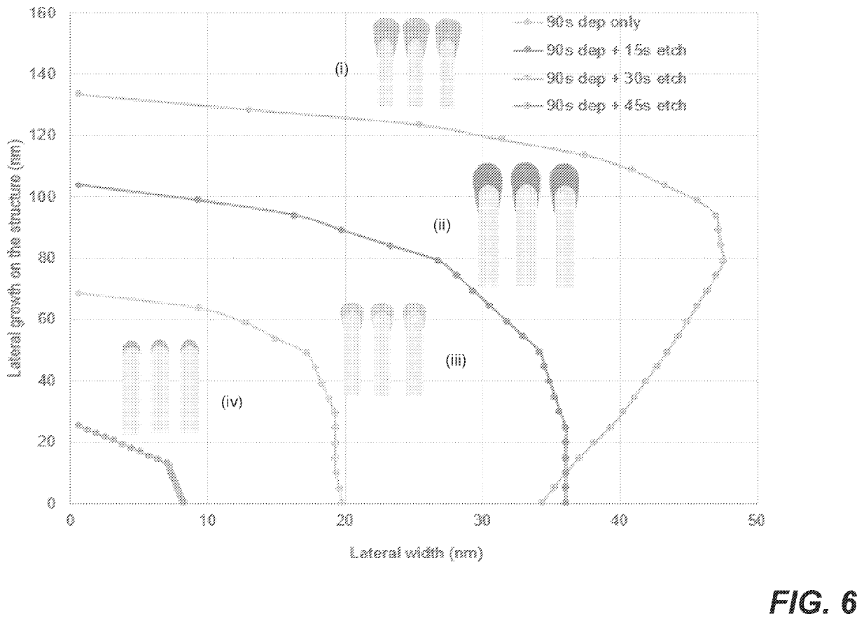

FIG. 6 is a graph with accompanying illustrations to portray how the shape of the non-conformal metal-doped film is affected by the duration of etching in accordance with certain disclosed embodiments. The deposition of tungsten carbide was performed by PECVD on an ONON patterned coupon with WF₆ precursor, H₂ reducing agent, CH₄/C₃H₆ hydrocarbon-precursor with an Ar inert carrier gas at a temperature of 400 °C. Etching was performed with NF₃ as the etchant with an Ar/He inert carrier gas mixture. Under conditions of deposition only, the non-conformal tungsten-doped carbon-containing film is wider than with an etch of varying durations. The longer the duration of the etch, the less wide the shape of the protective overlying metal-doped structure.

In FIG. 6, illustration (i) is a cross-sectional view of a non-conformal tungsten-doped carbon-containing film formed with exposure to deposition conditions for 90 seconds. Illustration (ii) is a cross-sectional view of a non-conformal tungsten-doped carbon-containing film formed with exposure to deposition conditions for 90 seconds followed by a 15 second etch. Illustration (iii) is a cross-sectional view of a non-conformal tungsten-doped carbon-containing film formed with exposure to deposition conditions for 90 seconds followed by a 30 second etch, and illustration (iv) is a cross-sectional view of a non-conformal tungsten-doped carbon-containing film formed with exposure to deposition conditions for 90 seconds followed by a 45 second etch.

The images illustrate that the non-conformal film can be formed in a particular desired shape, depending upon processing conditions. For example, the helmets or shapes which can be formed by the methods described include, but are not limited to: a shape with rounded edges at the top, but greater width near the top than at the bottom of the film as in illustration (i); or a shape with substantially the same width the entire height of the film but for rounded edges at the top of the film as in illustration (ii). In some embodiments, the helmet may have a height of about 20 to about 200 nm; about 40 to about 180 nm; or from about 75 to 145 nm.

### Apparatus

Another aspect involves an apparatus for processing a semiconductor substrate by depositing on a patterned semiconductor substrate a non-conformal metal-doped film, the apparatus including: a reaction chamber including the substrate; a plasma source coupled to the reaction chamber and configured to generate a plasma outside the reaction chamber; one or more first gas inlets coupled to the reaction chamber; a second gas inlet coupled to the reaction chamber; and a controller including instructions for performing the following operations: depositing on a patterned semiconductor substrate disposed in the chamber a non-conformal metal-doped film. The instructions may further include that the non-conformal metal-doped film be deposited by a chemical vapor deposition (CVD) based process using reactants for a carbide or carbon nitride and a metal dopant. The CVD process may be a plasma enhanced CVD (PECVD) process. The composition and processing conditions of the non-conformal metal-doped film may be tailored or tuned so that the film exhibits a particular desired non-conformal shape, such as a helmet. The description that following provides some details of apparatus, semiconductor chambers and tools suitable for implementation of the methods described herein and to fabricate the described devices.

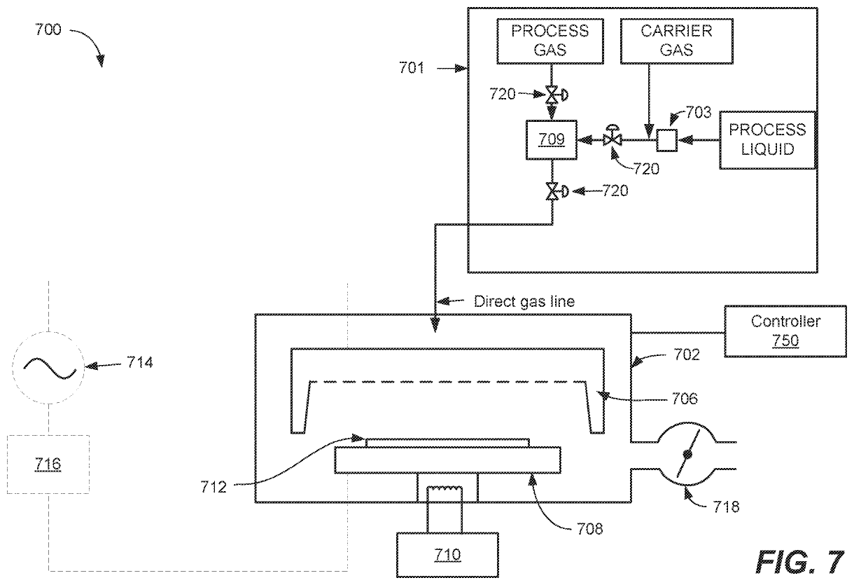

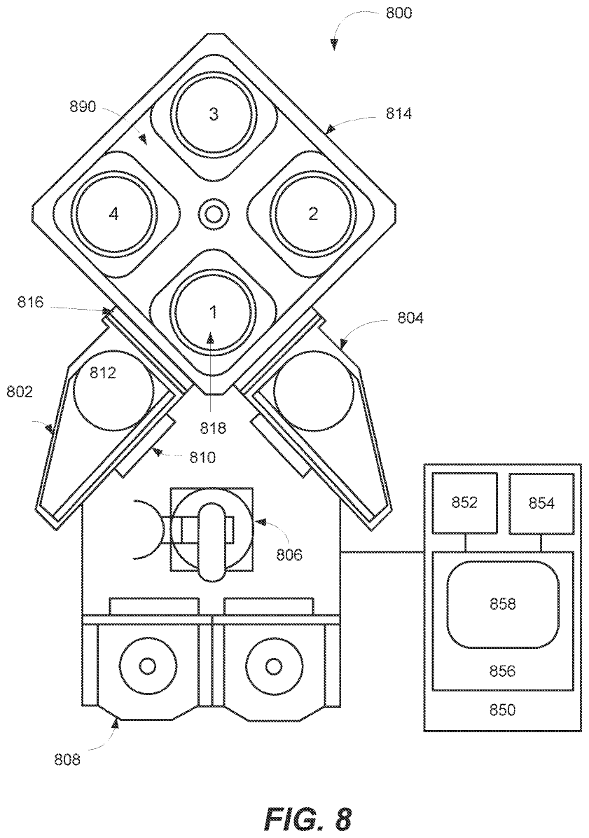

FIG. 7 depicts a schematic illustration of an embodiment of deposition process chamber 700 that may be suitable for depositing and processing films as described herein. The chamber may be operated as a chemical vapor deposition (CVD) chamber, in particular a plasma enhanced CVD (PECVD) chamber. The chamber 700 has a process chamber body 702 for maintaining a low pressure environment. A plurality of process stations 700 may be included in a common low pressure process tool environment. For example, FIG. 8 depicts an embodiment of a multi-station processing tool 800.

Referring again to FIG. 7, process station 700 fluidly communicates with reactant delivery system 701 for delivering process gases to a distribution showerhead 706. Reactant delivery system 701 includes a mixing vessel 709 for blending and/or conditioning process gases, such as a metal precursor gas or second reactant gas (e.g., a dopant reactant), for delivery to showerhead 706. One or more mixing vessel inlet valves 720 may control introduction of process gases to mixing vessel 709. Plasma may also be delivered to the showerhead 706 or may be generated in the process station 700. Reactant delivery system 701 may be configured to deliver process gases for depositing a doped oxide film over a substrate provided in the process station 700.

As an example, the embodiment of FIG. 7 includes a vaporization point 703 for vaporizing liquid reactant to be supplied to the mixing vessel 709. In some embodiments, vaporization point 703 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 703 may be heat traced. In some examples, mixing vessel 709 may also be heat traced. In one non limiting example, piping downstream of vaporization point 703 has an increasing temperature profile extending from approximately 100 °C to approximately 150 °C at mixing vessel 709.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 703. In one scenario, a liquid injector may be mounted directly to mixing vessel 709. In another scenario, a liquid injector may be mounted directly to showerhead 706.

In some embodiments, a liquid flow controller (LFC) upstream of vaporization point 703 may be provided for controlling a mass flow of liquid for vaporization and delivery to process station 700. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 706 distributes process gases toward substrate 712. In the embodiment shown in FIG. 7, the substrate 712 is located beneath showerhead 706 and is shown resting on a pedestal 708. Showerhead 706 may have any suitable shape and may have any suitable number and arrangement of ports for distributing process gases to substrate 712.

In some embodiments, pedestal 708 may be raised or lowered to expose substrate 712 to a volume between the substrate 712 and the showerhead 706. It will be appreciated that, in some embodiments, pedestal height may be adjusted programmatically by a suitable computer controller 750.

In another scenario, adjusting a height of pedestal 708 may allow a plasma density to be varied during plasma activation cycles in the process in embodiments where a plasma is ignited. At the conclusion of the process phase, pedestal 708 may be lowered during another substrate transfer phase to allow removal of substrate 712 from pedestal 708.

In some embodiments, pedestal 708 may be temperature controlled via heater 710. In some embodiments, the pedestal 708 may be heated to a temperature of at least about 400 °C, or in some embodiments, less than about 300 °C, such as about 250 °C, during deposition of non-conformal metal-doped films as described in disclosed embodiments. In some embodiments, the pedestal is set at a temperature between about 400 °C and about 600 °C for non-conformal metal-doped film deposition.

Further, in some embodiments, pressure control for process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to the process station 700.

In some embodiments, a position of showerhead 706 may be adjusted relative to pedestal 708 to vary a volume between the substrate 712 and the showerhead 706. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable computer controllers 750.

In some embodiments where plasma may be used as discussed above, showerhead 706 and pedestal 708 electrically communicate with a radio frequency (RF) power supply 714 and matching network 716 for powering a plasma. In some embodiments, the plasma energy may be controlled by controlling one or more of a process station pressure, a gas concentration, an RF source power, an RF source frequency, and a plasma power pulse timing. For example, RF power supply 714 and matching network 716 may be operated at any suitable power to form a plasma having a desired composition of radical species. Examples of suitable powers are included above. Likewise, RF power supply 714 may provide RF power of any suitable frequency. In some embodiments, RF power supply 714 may be configured to control high-and low-frequency RF power sources independently of one another. Example low frequency RF frequencies may include, but are not limited to, frequencies between 0 kHz and 500 kHz. Example high-frequency RF frequencies may include, but are not limited to, frequencies between 1.8 MHz and 2.45 GHz, or greater than about 13.56 MHz, or greater than 27 MHz, or greater than 180 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, one or more hardware parameters of the process station 700, including those discussed in detail below, may be adjusted programmatically by one or more computer controllers 750.

In some embodiments, instructions for a controller 750 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. It will be appreciated that these recipe phases may be further subdivided and/or iterated in any suitable way within the scope of the disclosed embodiments.

As described above, one or more process chambers may be included as stations in a multi station processing tool. FIG. 8 shows a schematic view of an embodiment of a multi station processing tool 800 that includes a processing chamber 814 having a plurality of processing stations in a low-pressure environment. The processing chamber 814 may be configured to maintain a low-pressure environment so that substrates may be transferred among the process stations without experiencing a vacuum break and/or air exposure.

The tool 800 further includes an inbound load lock 802 and an outbound load lock 804, either or both of which may include a remote plasma source. A robot 806 at atmospheric pressure is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 includes a remote plasma source, the wafer may be exposed to a remote plasma treatment in the load lock prior to being introduced into a processing chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 includes four process stations, numbered from 1 to 4 in the embodiment shown in FIG. 8. Each processing station may be configured to deposit non-conformal metal-doped film. Each processing station is supplied by a common mixing vessel (709, for example in FIG. 7) for blending and/or conditioning process gases prior to delivery to each processing station. Each process station depicted in FIG. 8 includes a process station substrate holder (shown at 818 for station 1) and process gas delivery line inlets. In some embodiments, one or more process station substrate holders 818 may be heated.

In some embodiments, each process station may have different or multiple purposes. For example, a process station may be switchable between an ultra-smooth PECVD process mode and a conventional PECVD or CVD mode. Additionally, or alternatively, in some embodiments, processing chamber 814 may include one or more matched pairs of ultra-smooth PECVD and conventional PECVD stations (e.g., a pair including an ultrasmooth PECVD SiO₂ station and a conventional PECVD SiN station). In another example, a process station may be switchable between two or more film types, so that stacks of different film types may be deposited in the same process chamber. While the depicted processing chamber 814 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a substrate handling system 890 for transferring substrates within processing chamber 814. In some embodiments, substrate handling system 890 may be configured to transfer substrates between various process stations and/or between a process station and a load lock. It will be appreciated that any suitable substrate handling system may be employed. Non-limiting examples include substrate carousels and substrate handling robots.

The multi-station processing tool 800 also includes an embodiment of a system controller 850 employed to control process conditions and hardware states of processing tool 800. For example, in some embodiments, system controller 850 may control one or more process parameters during a PECVD film deposition phase to control features of a deposited film, including the composition and thickness of the deposited film, etc.

System controller 850 may include one or more memory devices 856, one or more mass storage devices 854, and one or more processors 852. Processor 852 may include a CPU or computer, analog and/or digital input/output connections, stepper motor controller boards, etc.

In some embodiments, system controller 850 controls all of the activities of processing tool 800. System controller 850 executes machine-readable system control software 858 stored in mass storage device 854, loaded into memory device 856, and executed on processor 852. System control software 858 may include instructions for controlling the timing, mixture of gases, chamber and/or station pressure, chamber and/or station temperature, substrate temperature, target power levels, RF power levels, substrate pedestal, chuck and/or susceptor position, and other parameters of a particular process performed by processing tool 800. System control software 858 may be configured in any suitable way. For example, various process tool component subroutines or control objects may be written to control operation of the process tool components for performing various process tool processes. System control software 858 may be coded in any suitable computer readable programming language.

In some embodiments, system control software 858 may include input/output control (IOC) sequencing instructions for controlling the various parameters described above. For example, each phase of a PECVD process may include one or more instructions for execution by system controller 850. The instructions for setting process conditions for a PECVD process phase may be included in a corresponding PECVD recipe phase, for example a thick doped silicon oxide film deposition as described herein. In some embodiments, the PECVD recipe phases may be sequentially arranged, so that all instructions for a PECVD process phase are executed concurrently with that process phase.

Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto process station substrate holder 818 and to control the spacing between the substrate and other parts of processing tool 800.

A process gas control program may include code for controlling gas composition and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of processing tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 850 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

In some implementations, the system controller 850 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 850, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 850 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 850 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 850, in some implementations, may be a part of or coupled to a computer that is integrated with, coupled to the system, otherwise networked to the system, or a combination thereof. For example, the system controller 850 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the system controller 850 receives instructions in the form of data, which specify parameters for each of the processing steps to be performed during one or more operations. It should be understood that the parameters may be specific to the type of process to be performed and the type of tool that the system controller 850 is configured to interface with or control. Thus as described above, the system controller 850 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a chemical vapor deposition (CVD/PECVD) chamber or module, a plasma etch chamber or module, a track chamber or module, and any other semiconductor processing systems that may be associated or used in the fabrication and/or manufacturing of semiconductor wafers. Etching operations described herein, such as for etching nitride or oxide, may be performed in any suitable process chamber. In some embodiments, substrates may be etched in an adjustable gap capacitively coupled confined RF plasma reactor that may be used for performing the etching operations described herein.

As noted above, depending on the process step or steps to be performed by the tool, the system controller 850 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

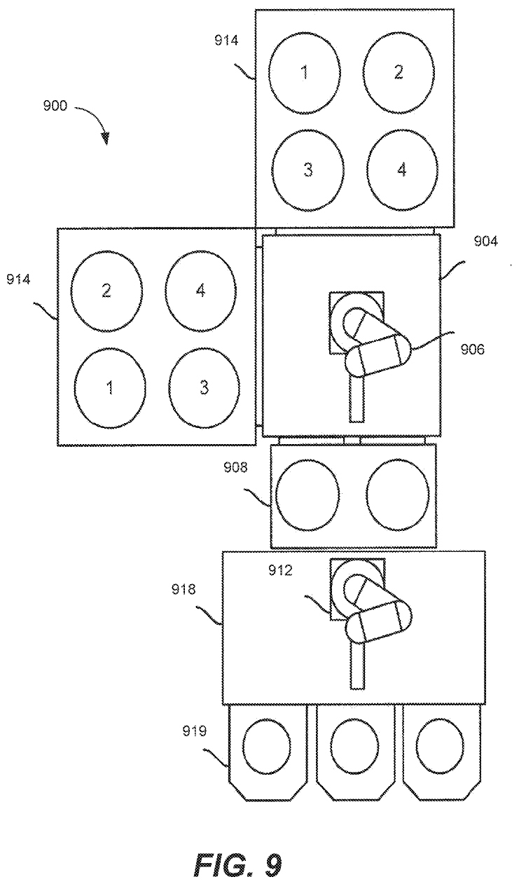

It will be appreciated that, in some embodiments, a low-pressure transfer chamber may be included in a multi-station processing tool to facilitate transfer between a plurality of processing chambers. For example, FIG. 9 schematically shows another embodiment of a multi-station processing tool 900. In the embodiment shown in FIG. 9, multi-station processing tool 900 includes a plurality of processing chambers 914 including a plurality of process stations (numbered 1 through 4). Processing chambers 914 are interfaced with a low-pressure transport chamber 904 including a robot 906 configured to transport substrates between processing chambers 914 and load lock 919. An atmospheric substrate transfer module 918, including an atmospheric robot 912, is configured to facilitate transfer of substrates between load lock 919 and pod 908. While not shown in FIG. 9, it will be appreciated that the embodiment of multi-station processing tool 900 may include a suitable system controller like the embodiment of system controller 850 shown in and described with reference to FIG. 8.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of forming a non-conformal metal-doped film on a patterned semiconductor substrate comprising:
providing a patterned semiconductor substrate in a process chamber, the patterned semiconductor substrate comprising a patterned mask layer; and
exposing the patterned semiconductor substrate to one or more cycles of (i) plasma-enhanced chemical vapor deposition and (ii) etching, wherein each cycle comprises
exposure to a metal-containing precursor, a hydrocarbon precursor and a reducing agent for 10 to about 150 seconds, to deposit a metal-doped carbon-containing layer over the patterned mask layer; and
exposure of the metal-doped carbon-containing layer over the patterned mask layer to an etchant for one to about 60 seconds, to form a non-conformal metal-doped film over the patterned mask layer.

2. The method of claim 1, wherein the non-conformal metal-doped film comprises tungsten-doped carbide, tungsten-doped carbonitride, ruthenium-doped carbonitride, ruthenium-doped carbide, molybdenum-doped carbide or a combination thereof.

3. The method of claim 1, wherein the hydrocarbon precursor comprises methane, ethane, ethylene, propylene, propyne, propane, butane, butylene, butadiene, acetylene or a combination thereof.

4. The method of claim 1, wherein the reducing agent comprises hydrogen, ammonia, hydrazine, silane, disilane, trisilane, germane, digermane, diborane or a combination thereof.

5. The method of claim 1, wherein the etchant comprises hydrogen, ammonia, boron trifluoride, nitrogen trifluoride, sulfur hexafluoride, phosphorus pentafluoride, tungsten hexafluoride or a combination thereof.

6. The method of claim 1, wherein exposing comprises one to twenty cycles of plasma-enhanced chemical vapor deposition and etching.

7. The method of claim 1, wherein exposing comprises one cycle of plasma-enhanced chemical vapor deposition and etching.

8. The method of claim 7, wherein one cycle of plasma-enhanced chemical vapor deposition and etching comprises exposure to a metal-containing precursor, a hydrocarbon precursor and a reducing agent for 30 seconds to about 95 seconds, and exposure to an etchant for 10 seconds to about 50 seconds.

9. The method of claim 1, wherein the process chamber is maintained at a temperature between about 200 °C to 650 °C.

10. The method of claim 1, wherein the patterned semiconductor substrate comprises features in the patterned mask layer and dielectric material under the patterned mask layer.

11. The method of claim 10, further comprising etching the dielectric material to form trenches in the dielectric material.

12. The method of claim 10, wherein the features in the patterned mask layer comprise pillars composed of the patterned mask layer.

13. The method of claim 12, wherein the non-conformal metal-doped film forms an overlayer on top of the pillars.

14. The method of claim 10, wherein the dielectric material comprises layers of silicon oxide and polysilicon or layers of silicon oxide and silicon nitride.

15. The method of claim 1, wherein the one or more cycles are performed in one process chamber.

16. The method of claim 1, wherein the non-conformal metal-doped film over the patterned mask layer has a rounded profile.

17. The method of claim 1, wherein the non-conformal metal-doped film comprises helmet-shaped deposits over the patterned mask layer.

18. The method of claim 1, wherein the non-conformal metal-doped film comprises tungsten-doped carbide and the metal-containing precursor comprises a tungsten-containing precursor.

19. The method of claim 18, wherein the tungsten-containing precursor comprises tungsten hexacarbonyl, tungsten pentachloride, tungsten hexachloride or tungsten hexafluoride.

20. The method of claim 18, wherein the tungsten-doped carbide comprises from about 10 to about 75 percent tungsten by weight.

21. An apparatus for processing patterned semiconductor substrates, the apparatus comprising:
a process chamber;
a substrate support for a patterned semiconductor substrate positioned within the process chamber, the patterned semiconductor substrate comprising a patterned mask layer;
a plasma generator configured to generate a plasma within the process chamber;
one or more gas inlets into the process chambers and associated flow-control hardware; and
a controller having at least one processor and a memory, wherein
the at least one processor and the memory are communicatively connected with one another, the at least one processor is at least operatively connected with the associated flow-control hardware, and
the memory stores computer-executable instructions for controlling the at least one processor to cause:
(i) positioning the patterned semiconductor substrate in the process chamber; and
(ii) exposing the patterned semiconductor substrate to one or more cycles of plasma-enhanced chemical vapor deposition and etching, wherein each cycle comprises exposure to a metal-containing precursor, a hydrocarbon precursor and a reducing agent for 10 to about 150 seconds, to deposit a metal-doped carbon-containing layer over the patterned mask layer; and
exposure of the metal-doped carbon-containing layer over the patterned mask layer to an etchant for one to about 60 seconds, to form a non-conformal metal-doped film over the patterned mask layer.
